(19) United States
(12) Patent Application Publication
(10) Pub. No.: US 2008/0129361 A1
(43) Pub. Date: Jun. 5, 2008

(54) METHOD AND SYSTEM FOR PROGRAMMABLE DELAYS ON TRANSPORT OUTPUTS

(76) Inventor: Rajesh Mamidwar, San Diego, CA (US)

Correspondence Address: MCANDREWS HELD & MALLOY, LTD, 500 WEST MADISON STREET, SUITE 3400, CHICAGO, IL, 60661, US

(21) Appl. No.: 11/567,015

(22) Filed: Dec. 5, 2006

(51) Int. Cl. H03H 11/26

(52) U.S. Cl. 327/261

(57) ABSTRACT

Methods and systems for controlling signals in a chip are described herein. Aspects of the invention may include receiving an input signal from a chip core and delaying the input signal utilizing a delay circuit prior to transmitting the input signal to an output port. The delay circuit may comprise a plurality of delay cells. The delay of the circuit may be determined by the number of enabled delay cells. The delay circuit may be programmed utilizing a delay select signal, which may select an input to a multiplexer to be coupled to an output of the multiplexer, which may be coupled to a chip output pad. The chip core may comprise an MPEG-2 encoder, and the delay circuit may be utilized to delay MPEG-2 encoded transport signals.

### CROSS-REFERENCE TO RELATED APPLICATIONS/INCORPORATION BY REFERENCE

[Not Applicable]

### FEDERALLY SPONSORED RESEARCH OR DEVELOPMENT

[Not Applicable]

### MICROFICHE/COPYRIGHT REFERENCE

[Not Applicable]

### FIELD OF THE INVENTION

Certain embodiments of the invention relate to data signal transport delay. More specifically, certain embodiments of the invention relate to a method and system for programmable delays on transport outputs.

### BACKGROUND OF THE INVENTION

The introduction of broadband networks, headend and terminal devices such as set-top boxes, and media such as DVD disks recorded with digitally compressed audio, video and data signals, for example, which utilize motion Picture Expert Group (MPEG) compression standards, may provide sound and picture quality that is virtually indistinguishable from the original material. One of the most popular MPEG standards is MPEG-2, which provides the necessary protocols and infrastructure that may be used for delivering digital television or DVD contents with compressed audio, video and data signals. A detailed description of the MPEG 2 standard is published as ISO/IEC Standard 13818.

In addition to the increasing speed of Internet transactions, continued advancement of motion picture content compression standards permit high quality picture and sound while significantly reducing the amount of data that must be transmitted. An encoded bitstream, such as an MPEG-2 bitstream, comprises different types of data. For example, an MPEG-2 bitstream may comprise audio information, video information, and additional data. A transmitted MPEG-2 bitstream may be received by a set-top box (STB), for example, and the STB may further process the received bitstream.

The frequency of transport clocks can range from 20 to 100 MHz. As the frequency nears 100 MHz, board level timing for routing these signals can become critical, thus necessitating precise chip level timings. This can be made even more difficult in cases where signals are routed to different chip pins for different configurations or packages.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method for programmable delays on transport outputs, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating data transport between chips, in accordance with an embodiment of the invention.

FIG. 2 is a block diagram of an exemplary MPEG decoding system, in accordance with an embodiment of the invention.

FIG. 3 is a block diagram of a transport programmable delay, in accordance with an embodiment of the invention.

### DETAILED DESCRIPTION OF THE INVENTION

Certain aspects of the invention may be found in a method and system for controlling signals in a chip. Exemplary aspects of the invention may include receiving input signals from the chip core and delaying input signals utilizing a delay circuit prior to sending the input signals to the chip output pads. The delay circuit may comprise a plurality of delay cells. The amount of delay that may be provided by the circuit may be determined by the number of delay cells that are programmably enabled. The delay circuit may be programmed utilizing a delay select signal, which may select which input to a multiplexer to be coupled to the output of the multiplexer. Thus the selected input may pass through the multiplexer to the chip output pad. The chip core may comprise an MPEG-2 decoder, and the delay circuit may be utilized to delay MPEG-2 decoded transport or other signals.

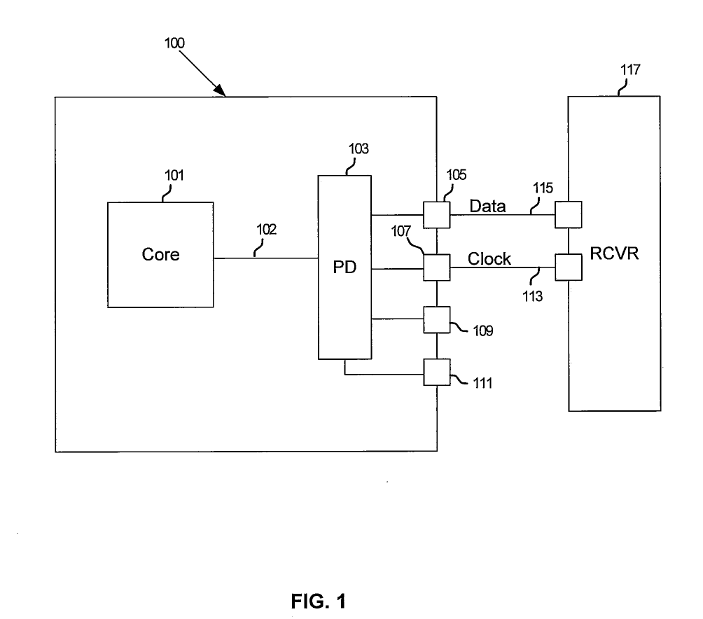

FIG. 1 is a block diagram illustrating data transport between chips, in accordance with an embodiment of the invention. Referring to FIG. 1, there is shown a transmit chip 100, chip output pads 105, 107, 109, 111, a receiver chip 117, and receiver chip input pads 113, 115. The transmit chip 100 may comprise a chip core 101 and a programmable delay circuit 103. The chip core 101 may comprise suitable circuitry, logic, and/or code for supplying an MPEG-2 decoded transport stream 102. The programmable delay circuit 103 may comprise suitable circuitry, logic, and/or code for delaying the MPEG-2 decoded transport stream 102. The chip output pads 105, 107, 109, and 111 may comprise a path for conduction of signals out of the chip 101. The transmit chip 100 may comprise the chip core 101 and the programmable delay circuit 103. The receiver chip 117 may comprise suitable circuitry, logic, and/or code for receiving signals from the transmit chip 100. For example, the receiver chip 117 may comprise a trans-coder chip, a set-top chip, an external decoder chip, or an external 1394 interfacing chip. The transmit chip 200 and the receiver chip 117 may be coupled by the data line 115 and the clock line 113.

In operation, the chip core 101 may generate an MPEG-2 decoded transport stream 102. The transport stream 102 may then be communicated to the programmable delay circuit 103, which may delay the signal as necessary. The output of the programmable delay circuit 103 may then be communicated to the chip output pads 105, 107 and then to the receiver chip input pads 113, 115. The signal received by the receiver chip 117 may then be decoded for display or coupled to an external system, for example.

In another embodiment of the invention, the encoded transport stream may be any electrical signal from an integrated circuit to be communicated to an external chip or system where the timing of the output signal may be specified.

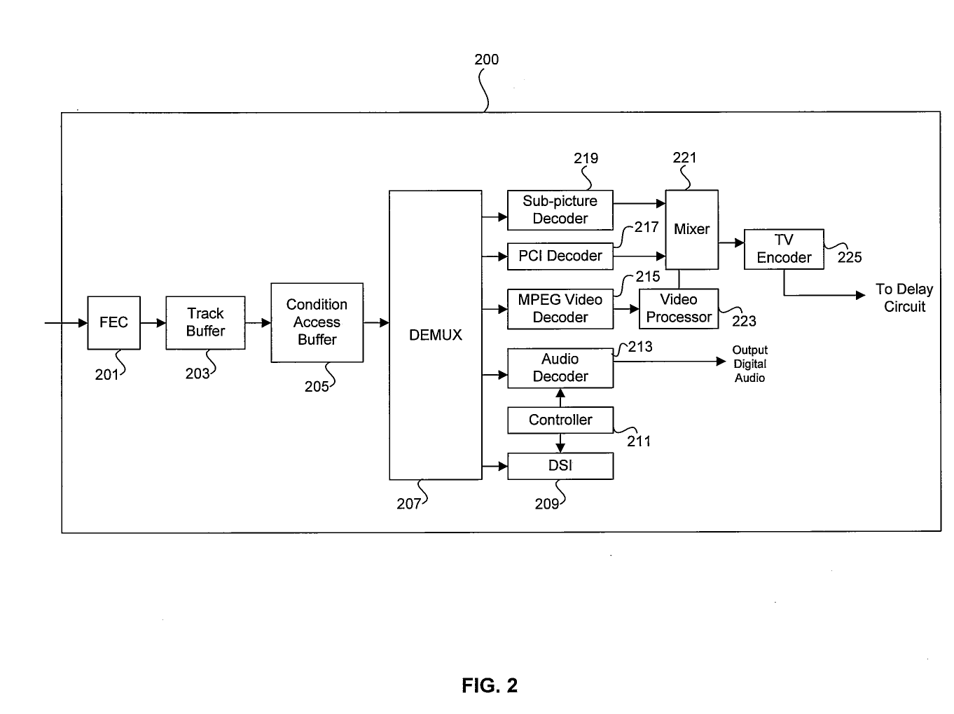

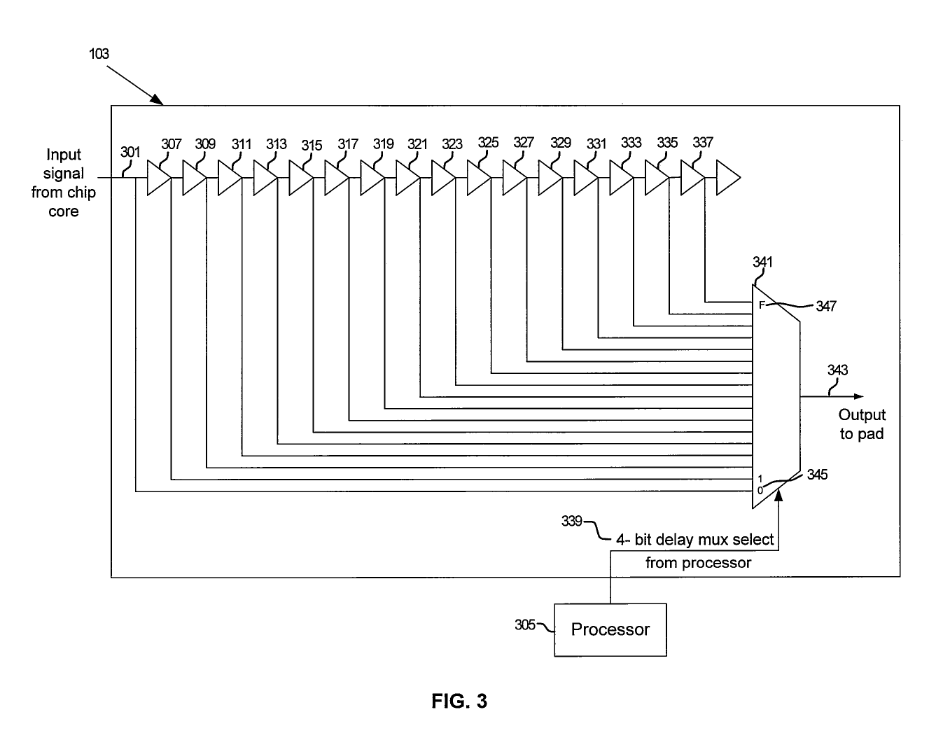

FIG. 2 is a block diagram of an exemplary MPEG decoding system that may be utilized in accordance with an embodiment of the invention. The MPEG decoding system 200 may be, for example, a set-top box. Referring to FIG. 3, the MPEG decoding system 300 may comprise a forward error correction (FEC) processing block 201 and a track buffer 203. The track buffer 203 may be used to buffer and assemble data packets for further processing. The packets may be processed by a conditional access circuit 205 that may be configured to control propagation of the packets through the de-multiplexer (DEMUX) 207 and into respective video and audio processing paths. The output of the DEMUX 207 may include various kinds of packetized elementary streams (PES), including audio, video, presentation control information (PCI), sub-picture information, and data search information (DSI) streams. The de-multiplexed PCI in the PES may be buffered prior to being decoded by the PCI decoder 217.

The sub-picture information in the PES may be buffered and decoded by the sub-picture decoder 219. The de-multiplexed video stream in the PES may be decoded by the MPEG video decoder 215. The video processor 223 may be configured to process the output from the MPEG video decoder 215. The video processor 223 may be a microprocessor or an integrated circuit (IC). Subsequent to processing of the MPEG video, mixer 221 may combine the outputs of the PCI decoder 217, the video processor 223 and the sub-picture decoder 219 to form a composite video signal. The output of mixer 221 may thereafter be encoded in a conventional television signal format such as PAL, SECAM, or NTSC by the TV encoder 225. The output of the TV encoder 225 may be a digital video signal to be communicated to programmable delay circuit 103 as disclosed in FIG. 1.

The audio portion of the PES may be buffered and decoded by audio decoder 213. The output of the audio decoder 213 may be a digital audio signal. The audio decoder 213 may include a frame buffer sufficient for temporarily storing audio frames prior to decoding. The controller 211 may control the operation of audio decoder 213 and DSI 209. The controller 211 may be configured to utilize DMA to access to data in track buffer 203 or any other associated memory (not shown). The digital output signal generated by audio decoder may also be communicated to a programmable delay cell.

FIG. 3 is a block diagram of a transport programmable delay, in accordance with an embodiment of the invention. Referring to FIG. 3, there is shown an exemplary programmable delay circuit 103. The programmable delay circuit 103 may comprise delay cells 307, 309, 311, 313, 315, 317, 319, 321, 323, 325, 327, 329, 331, 333, 335, and 337, a processor 305 and a multiplexer 341. The programmable delay circuit 103 may comprise suitable circuitry, logic and/or code for delaying an input signal before sending this signal to an output pad. The multiplexer 341 may be a 16 to 1 multiplexer, for example, depending on the number of delay cells, or amount of delay required.

The input signal 301 from the chip core, which may be substantially similar to MPEG-2 decoded transport stream 102 described with respect to FIG. 1, may be communicated directly to the output of the multiplexer 341 as well as to the first delay cell 307, the output of which may be communicated to another input of the multiplexer 441 and to the input of the next delay cell 409, etc . . . until the delay cell 337 which may be communicated to the last input 347 of the multiplexer 341. The total delay of the programmable delay circuit 103 may be determined by the number of delay cells that may be programmably enabled. The output 343 of the multiplexer 341 may be coupled to a chip output pad or port. This pad may be substantially similar to the transmit chip output pad 105 described with respect to FIG. 1.

In operation, an exemplary four bit delay MUX select signal 339 may select which input signal is to be coupled to an output of the multiplexer 341. The four bit delay MUX select signal 339 may be supplied by the processor 305, for example. For minimal delay, the input connection 345, labeled ‘0’ on the multiplexer 341 may be selected, which may communicate the input signal 301 from the chip core to the output of the multiplexer 341, without passing through a delay cell. The output signal of the first delay cell 307 may have one unit delay time, and the signal that passes through all sixteen delay cells in this example may result in a maximum delay, or sixteen times the unit delay time, which may be selected from the input connection 347, labeled ‘F’, on the multiplexer 341. In this manner, delay times in increments of a single delay cell may be selected. The delay of the delay cells may be adjustable determined by the circuit components within each delay cell. In addition, the number of delay cells may be adjusted to result in a longer or shorter delay.

In an embodiment of the invention, a method and system is described for controlling signals in a chip. Aspects of the invention may include receiving input signals 102 from the chip core and delaying input signals utilizing a delay circuit 103 prior to sending the input signals to the chip output pads 105, 107. The programmable delay circuit 103 may comprise a plurality of delay cells 307, 309, 311, 313, 315, 317, 319, 321, 323, 325, 327, 329, 331, 333, 335 and 337. The delay of the circuit may be determined by the number of delay cells. The programmable delay circuit 103 may be programmed utilizing a delay select signal 339, which may select an input to a multiplexer 441 to be coupled to an output of the multiplexer 441, which may be coupled to a chip output pad 105. The chip core 101 may comprise an MPEG-2 decoder 200, and the programmable delay circuit 103 may be utilized to delay MPEG-2 decoded transport signals 102.

Certain embodiments of the invention may comprise a machine-readable storage having stored thereon, a computer program having at least one code section for communicating information within a network, the at least one code section being executable by a machine for causing the machine to perform one or more of the steps described herein.

Accordingly, aspects of the invention may be realized in hardware, software, firmware or a combination thereof. The invention may be realized in a centralized fashion in at least one computer system or in a distributed fashion where different elements are spread across several interconnected computer systems. Any kind of computer system or other apparatus adapted for carrying out the methods described herein is suited. A typical combination of hardware, software and firmware may be a general-purpose computer system with a computer program that, when being loaded and executed, controls the computer system such that it carries out the methods described herein.

One embodiment of the present invention may be implemented as a board level product, as a single chip, application specific integrated circuit (ASIC), or with varying levels integrated on a single chip with other portions of the system as separate components. The degree of integration of the system will primarily be determined by speed and cost considerations. Because of the sophisticated nature of modern processors, it is possible to utilize a commercially available processor, which may be implemented external to an ASIC implementation of the present system. Alternatively, if the processor is available as an ASIC core or logic block, then the commercially available processor may be implemented as part of an ASIC device with various functions implemented as firmware.

The present invention may also be embedded in a computer program product, which comprises all the features enabling the implementation of the methods described herein, and which when loaded in a computer system is able to carry out these methods. Computer program in the present context may mean, for example, any expression, in any language, code or notation, of a set of instructions intended to cause a system having an information processing capability to perform a particular function either directly or after either or both of the following: a) conversion to another language, code or notation; b) reproduction in a different material form. However, other meanings of computer program within the understanding of those skilled in the art are also contemplated by the present invention.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A method for controlling signals in a chip, the method comprising:
receiving an input signal from a chip core; and
delaying said received input signal utilizing a programmable delay circuit having a variable delay prior to communicating said received input signal to an output port.

2. The method according to claim 1, wherein said programmable delay circuit comprises a plurality of delay cells.

3. The method according to claim 2, wherein an amount of delay provided by said programmable delay circuit is determined by a number of said plurality of delay cells that are programmably enabled.

4. The method according to claim 1, comprising programming said delay circuit utilizing a delay select signal.

5. The method according to claim 4, wherein said delay select signal selects one of a plurality of inputs to a multiplexer to be coupled to an output of said multiplexer.

6. The method according to claim 4, wherein said delay select signal is generated by a processor.

7. The method according to claim 1, wherein said chip core comprises an MPEG-2 decoder.

8. The method according to claim 7, wherein said MPEG-2 decoder generates said received input signal.

9. The method according to claim 8, wherein said received input signal comprises a transport signal.

10. The method according to claim 9, wherein said delaying is applied to said transport signal.

11. A system for controlling signals in a chip, the system comprising:
one or more circuits for receiving an input signal from a chip core; and
said one or more circuits comprising a delay circuit for delaying said input signal prior to communicating said input signal to an output port.

12. The system according to claim 11, wherein said one or more circuits comprises a plurality of delay cells.

13. The system according to claim 12, wherein an amount of delay provided by said programmable delay circuit is determined by a number of said plurality of delay cells that are programmably enabled.

14. The system according to claim 11, wherein said one or more circuits is controlled by a delay select signal.

15. The system according to claim 14, wherein said delay select signal selects one of a plurality of inputs to a multiplexer to be coupled to an output of said multiplexer.

16. The system according to claim 14, wherein said delay select signal is generated by a processor.

17. The system according to claim 11, wherein said chip core comprises an MPEG-2 decoder.

18. The system according to claim 17, wherein said MPEG-2 decoder generates said received input signal.

19. The system according to claim 18, wherein said received input signal comprises a transport signal.

20. The system according to claim 19, wherein said delaying is applied to said transport signal.

21. A machine-readable storage having stored thereon, a computer program having at least one code section for controlling signals in a chip, the at least one code section being executable by a machine for causing the machine to perform steps comprising:
receiving an input signal from a chip core; and
delaying said input signal via a programmable delay circuit prior to communicating said input signal to an output port.

22. The machine readable storage according to claim 21, wherein said at least one code section comprises code for delaying said input signal utilizing a plurality of delay cells.

23. The machine readable storage according to claim 22, wherein said at least one code section comprises code for determining said delaying via a number of said plurality of delay cells that are programmably enabled.

24. The machine readable storage according to claim 21, wherein said at least one code section comprises code for programming said delay circuit utilizing a delay select signal.

25. The machine readable storage according to claim 24, wherein said at least one code section comprises code for selecting one of a plurality of inputs to a multiplexer to be coupled to an output of said multiplexer utilizing said delay select signal.

26. The machine readable storage according to claim 24, wherein said at least one code section comprises code for generating said delay select signal utilizing a processor.

27. The machine readable storage according to claim 21, wherein said at least one code section comprises code for said chip core comprising an MPEG-2 decoder.

28. The machine readable storage according to claim 27, wherein said at least one code section comprises code for generating said received input signal utilizing said MPEG-2 decoder.

29. The machine readable storage according to claim 28, wherein said at least one code section comprises code for generating said received input signal comprising a transport signal.

30. The machine readable storage according to claim 29, wherein said at least one code section comprises code for delaying said transport signal.
